(19) United States
(12) Patent Application Publication
(10) Pub. No.: US 2010/0258180 A1
(43) Pub. Date: Oct. 14, 2010

(54) Method of forming an indium-containing transparent conductive oxide film, metal targets used in the method and photovoltaic devices utilizing said films

(76) Inventors: Yuepeng Deng, (US); Louay Eldada, (US); Robert Oswald, (US)

Correspondence Address: WATOV & KIPNES, P.C., P.O. Box 247, Princeton Junction, NJ, 08550, US

(21) Appl. No.: 12/658,203

(22) Filed: Feb. 4, 2010

Related U.S. Application Data
(60) Provisional application No. 61/206,877, filed on Feb. 4, 2009.

(51) Int. Cl. H01L 31/0216; C23C 14/34

(52) U.S. Cl. 136/256; 204/192.29

(57) ABSTRACT

A method of forming an indium-containing transparent conductive oxide by reactive sputtering a metal target containing indium in an oxygen containing atmosphere and then depositing the resulting indium oxide on a substrate. Metal targets used in the method and photovoltaic devices utilizing the transparent conductive oxides are also disclosed.

### RELATED APPLICATION

This application claims priority of U.S. Provisional Patent Application No. 61/206,877 filed Feb. 4, 2009.

### FIELD OF THE INVENTION

The present invention relates generally to the field of forming transparent conductive oxide films and particularly to the formation of transparent conductive oxide films by reactive sputtering of a metal target containing indium.

### BACKGROUND OF THE INVENTION

Transparent conductive oxides (TCO) in the form of thin films are useful as an electrical contact in a variety of applications including photovoltaics (e.g. the fabrication of solar electric panels) and in flat-panel displays.

It is known in the art to form TCOs by sputtering aluminum-doped zinc oxide or indium zinc oxides from a ceramic (non-metal) target. Ceramic targets are desirable because they achieve relatively high performance and are generally reliable. Despite these advantages, ceramic targets suffer from a number of disadvantages. The deposition rates of the TCO from a ceramic target are lower than desired, which adds to the time and cost of depositing the TCO and forming solar panels. In addition, the thickness of the TCO formed from conventional aluminum-doped zinc oxide ceramic targets exceeds what is necessary to obtain a desired conductivity. Still further sputtering of aluminum-doped zinc oxide ceramic targets requires relatively high temperatures adding to the cost of the process.

It is therefore desirable to provide a method of producing transparent conductive oxide films in a manner which is cost effective and yet achieves desired high performance and high reliability.

### SUMMARY OF THE INVENTION

The present invention is generally directed to a method of forming a transparent conductive oxide film useful for the production of solar cells, flat panel displays and the like. The method employs reactive sputtering from a metal target. Reactive sputtering requires bombarding a metal target in an oxygen containing atmosphere so that the metal atoms react with oxygen to form the corresponding oxide which is deposited on a suitable substrate. In the present invention, the metal target at least includes indium. Thus, the reactive sputtering process of the present invention leads to the formation of an indium-containing transparent conductive oxide. The present method is a departure from conventional methods which utilize ceramic targets containing oxides such as aluminum-doped zinc oxides and indium zinc oxides.

In one embodiment of the present invention, there is provided:

A method of forming an indium-containing transparent conductive oxide film comprising:
a) reactive sputtering from a metal target comprising indium in an oxygen-containing atmosphere to form an indium-containing oxide; and
b) depositing the indium-containing oxide on a substrate to form said transparent conductive oxide film.

In a further embodiment of the invention, the method is conducted with a rotatable cylindrical target which provides a more uniform magnetic field distribution and thus obtains more efficient use of the target material.

In a further embodiment of the invention, there is provided a metal target comprising indium and zinc which can be sputtered in the presence of oxygen to form an indium-zinc transparent conductive oxide.

In a still further embodiment of the invention, there is provided a photovoltaic device, as for example a solar cell, employing an indium-containing transparent conductive oxide film formed by the method described above.

### DETAILED DESCRIPTION OF THE DRAWINGS

The following drawings in which like reference characters indicate like parts are illustrative of embodiments of the invention and are not intended to limit the invention as encompassed by the claims forming part of the application.

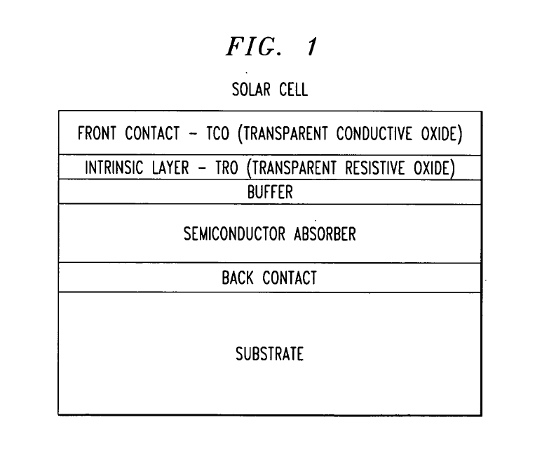

FIG. 1 is a schematic view of a solar cell showing the relative positioning of the principal layers of the solar cell including a transparent conductive oxide film formed in accordance with the present invention;

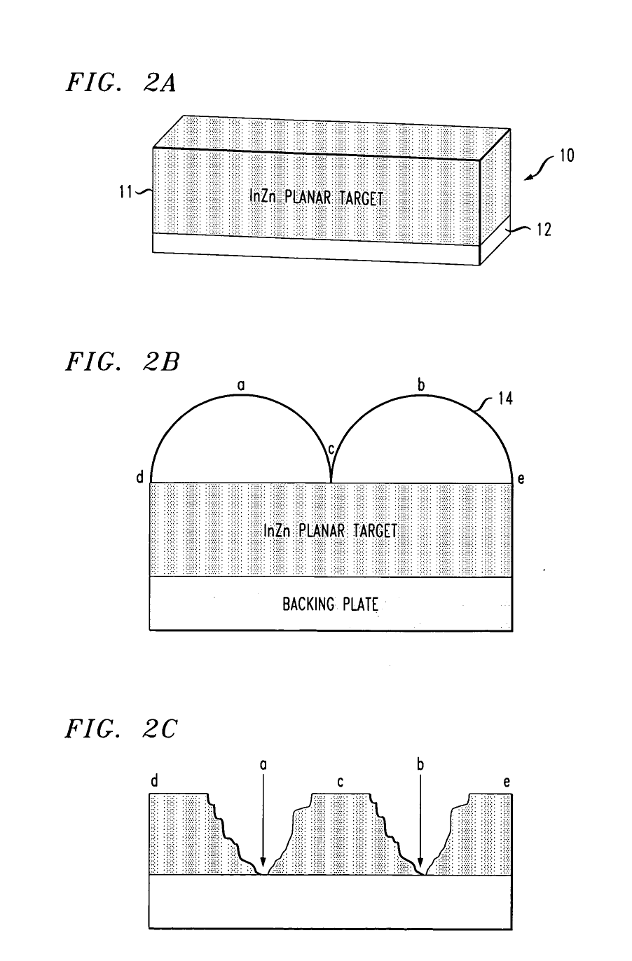

FIGS. 2A-2C are graphic views showing an embodiment of a planar metal target of indium-zinc used in a reactive sputtering process to form the transparent conductive oxide layer;

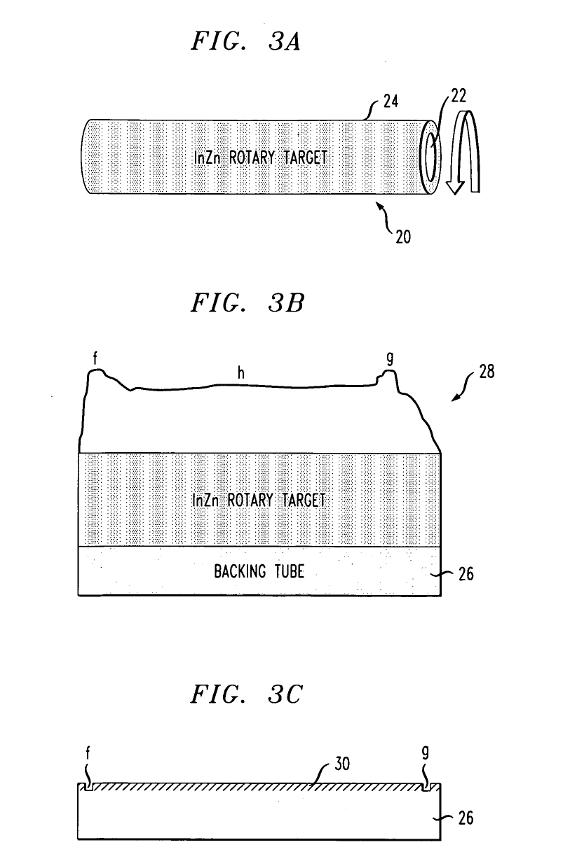

FIGS. 3A-3C are graphic views showing an embodiment of a rotatable metal target of indium-zinc in the form of a rotatable cylinder used in a reactive sputtering process to form the transparent conductive layer; and

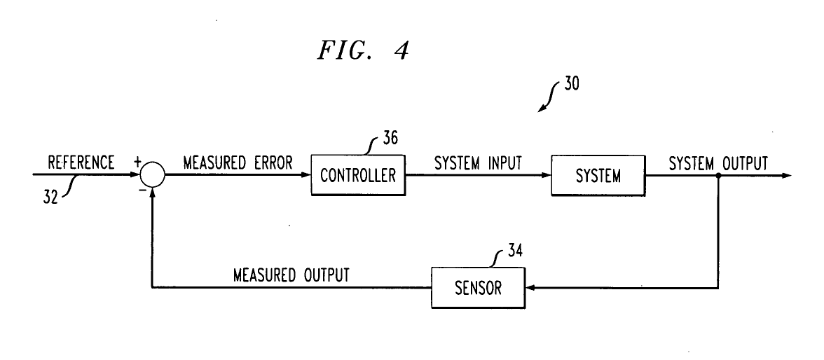

FIG. 4 is a schematic view of a closed-loop feedback control system for controlling the oxygen flow in the reactive sputtering process of the present invention.

### DETAILED DESCRIPTION OF THE INVENTION

The present invention is generally directed to a method of forming a transparent conductive oxide film (TCO) on a substrate which can be used as a front contact in the formation of articles such as solar cells and flat display panels. As shown in FIG. 1, a typical solar cell known in the art is identified by reference number 1. The solar cell has a substrate 2 made of a supporting material such as glass covered by a back contact 3 composed of, for example, molybdenum. An absorber layer 4 in the form of a thin film is spaced between the back contact and a front contact 5 comprised of the transparent conductive oxide. The prior art TCO's have been made from indium-tin oxides or aluminum-doped zinc oxides sputtered from ceramic targets. The absorber layer 4 is typically a layer comprised of copper-indium selenide (CIS), copper-gallium selenide (CGS), copper-indium-gallium-selenide (CIGS and CIGSS).

A buffer layer 6, typically made of gallium and/or indium oxide is positioned above the absorber layer 4. Optionally a transparent resistive oxide (TRO) layer 7 is provided between the front contact 5 and the buffer 6. The TRO, also referred to as an intrinsic layer, is often made from zinc oxide obtained from sputtering of a ceramic target comprised of zinc oxides or reactive sputtering from a metal zinc target. The TRO is a low carrier density material which prevents the flow of electrons between the front contact 5 and the absorber layer 4.

In accordance with the present invention, there is provided a method of forming the transparent conductive oxide by sputtering a metal target, preferably comprised of indium and zinc, in a controlled oxygen atmosphere as hereinafter described, to produce a thin film comprised of indium and zinc oxide having properties particularly suited for use as a front contact of a solar cell.

As compared with conventional TCO films made of aluminum-zinc oxide, the TCO films of the present invention are thinner while exhibiting greater light transmission and lower sheet resistance (ohm/square). In particular, to achieve similar sheet resistance, the TCO of the present invention is thinner, typically only about half as thick as needed for aluminum-zinc oxide films and exhibits light transmission gains of 3-4%.

The method of the present invention is carried out by sputtering an indium-zinc target with a gas mixture that consists of inert gas and reactive gas (e.g. oxygen). The principles of reactive sputtering are described in Reactive Sputter Deposition, Springer Series in Materials Science, Volume 109. Eds. Diederik Depla and Stijn Mahieu (2008). Inert gases such as argon are preferred gases for sputtering the metal target. The shape of the metal target can affect the cost of producing the TCO. In one embodiment of the invention, the target is a planar target in the shape of a rectangular solid. A more preferred metal target is in the form of a rotatable cylinder.

As shown in FIG. 2A, a planar target 10 made of indium-zinc (In—Zn) is comprised of an In—Zn layer 11 situated on a backing plate 12. The layer 11 is bombarded with an inert gas in an oxygen controlled environment to deposit indium-zinc oxide as the TCO thin film. The indium zinc layer 11 is comprised of InₓZn₁₋ₓ wherein x is from about 0.01 to 0.95, preferably from about 0.6 to 0.9.

During the sputtering process, a magnetic field 14 (shown in FIG. 2B) is established proximate the planar target. The intensity of the magnetic field over the length of the target (i.e. magnetic field distribution) is greatest at locations (a) and (b), respectively and decreases toward the center (c) and endpoints (d) and (e). Accordingly, the pattern of release of indium and zinc from the target is greatest at locations (a) and (b) where the intensity of the magnetic field is the greatest. As can be observed from FIG. 2C, the useful life of the planar target is limited to the extent that the quantity of indium-zinc is exhausted at locations (a) and (b). Conversely, the metal remaining at locations (d), (c), and (e) is unused, which makes the planar target use somewhat inefficient.

As shown in FIGS. 2A-2C, the pattern of usage of the target metal for reactive sputtering in the presence of oxygen is non-uniform and correlates to the magnetic field distribution. Target utilization may typically be in the range of 25-30%.

A more uniform magnetic field distribution is shown in the embodiment of FIGS. 3A-3C.

In accordance with a preferred embodiment of the invention, the metal target is in the form of a rotatable cylinder which during the sputtering process provides a relatively uniform magnetic field distribution. Referring to FIG. 3A, there is shown an indium-zinc target in the form of a rotatable cylinder (i.e. a rotary target). The rotary target 20 has a hollow core 22 and a shell 24 comprised of the target metal (e.g. indium-zinc) which is secured to a support or backing tube 26. The target is rotated during the sputtering process to generate a relatively uniform magnetic field 28 as shown in FIG. 3B. The magnetic field distribution is slightly higher than average at the respective ends (f) and (g) of the target, but is relatively continuous over much of the length (h) of the target. Because the magnetic field is relatively uniform over much of the length of the target, utilization of the target material is more uniform, often achieving 70-80% utilization.

Referring to FIG. 3C, there is shown a representation of a pattern of target erosion typically obtained for a rotary target. Much of the target metal has been released for forming the transparent conductive oxide. Only a relatively small amount of the target material 30 remains on the backing tube 26. Utilization of the target material is terminated at locations (f) and (g) because the slightly higher than average magnetic field distribution at the respective ends (f) and (g) of the rotary target (see FIG. 3B) fully erodes the target metal at these locations.

The indium-zinc metal target in either the planar or rotary form can be sputtered under moderate pressure of about 3 to 10 mTorr, preferably about 7 m Torr at a moderate power level of about 3 to 15 kW, preferably at about 10 kW. The TCO film produced in this manner provides a film with a sheet resistance of from about 10 to 90 ohm/square, preferably about 20 ohm/square and a light transmission rate of at least 85% at a thickness of only about 200 to 250 nm, which is up to half the thickness of a transparent conductive film made of aluminum doped zinc oxide from a ceramic target.

The benefits of using metal targets to produce the transparent conductive oxide are realized in part by controlling the oxygen atmosphere during the sputtering process. If the oxygen content exceeds a desirable level, then the TCO film will be less conductive because of low carrier concentration due to lack of oxygen vacancies. If the oxygen content falls below a desirable level, then the TCO film will exhibit light transmission and be more metal-like due to loss of mobility.

Accordingly, in a further embodiment of the invention, means are provided to control the oxygen atmosphere during the sputtering process. In a preferred embodiment, a feedback control system is used to monitor and control oxygen levels by associating the oxygen level with a monitorable variable of the system. Such monitorable variables include voltage, O₂ partial pressure and plasma emission.

Referring to FIG. 4, there is shown a schematic view of a feedback control system in which a select variable as mentioned above is associated with oxygen levels. The variable is monitored and compared to a standard which correlates with adjustments that may be necessary to the oxygen levels. The feedback control system of FIG. 4 will be explained below in which voltage is employed as the select variable.

The feedback control system 30 is comprised of a reference 32 which stores a target voltage set point. The target voltage is a voltage level that correlates with a desirable oxygen level. The desirable oxygen level is that flow of oxygen into the system which produces a desirable transparent conductive oxide by the reaction of oxygen with metal from the metal target (e.g. InZn).

A sensor 34 continuously measures the actual voltage in the system and generates a signal (measured output) corresponding to the measured voltage which is sent continuously or intermittently to the reference 32. When a deviation between the target voltage and the actual voltage is detected, a signal is sent to a controller 36 which monitors the mass flow of oxygen to the system. The controller adjusts the flow of oxygen (system input) until the actual voltage and target voltage are sufficiently similar so that the deviation between the target and actual voltage is either eliminated or sufficiently small that the flow of oxygen to the system is acceptable. For example, if the actual voltage exceeds the target voltage by an amount sufficient to cause a positive deviation (i.e. +deviation), oxygen flow will be increased. Conversely, if the actual voltage is less than the target voltage by an amount sufficient to cause a negative deviation (i.e. −deviation), oxygen flow will be decreased.

The feedback control system described in connection with FIG. 4 can be modified to employ O₂ partial pressure as the monitorable variable. In this embodiment, the reference is configured to establish an O₂ partial pressure set point. The sensor detects the actual O₂ pressure while the controller adjusts the oxygen flow to compensate for changes in the O₂ partial pressure. The system output monitors the actual O₂ partial pressure as detected by the sensor. The system input corresponds to a signal corresponding to the flow of oxygen from the controller to provide a desirable flow of oxygen to the reactive sputtering process.

Another use of the feedback control system employs O₂ plasma emission as the monitorable variable. In this embodiment, the reference is configured to establish an O₂ plasma emission set point. The sensor detects the actual O₂ plasma emission while the controller adjusts the oxygen flow to compensate for changes in the O₂ plasma emission. The system output monitors the actual O₂ plasma emission as detected by the sensor. The system input corresponds to the flow of oxygen from the controller to provide a desirable amount of oxygen for the reactive sputtering process.

The present invention may also provide for a transparent resistive oxide (TRO) layer to protect the photovoltaic device from an undesirable flow of electrons.

As indicated in connection with FIG. 1, solar panels employing a TCO in accordance with the present invention may also include a transparent resistive oxide layer between the TCO and the buffer. It is preferred in the present invention to employ a TRO comprised of indium-gallium-zinc oxide (IGZO) and/or indium-aluminum-zinc oxide (IAZO).

The TRO can be produced using metal targets having a desired metal composition (e.g. indium, gallium and zinc) in a manner similar to the method for producing the TCO. For example, a metal target comprised of indium, gallium and zinc is sputtered in a controlled oxygen atmosphere. The target may be planar or preferable a rotary target and the system may control the oxygen levels by employing a feedback control system as described in connection with FIG. 4.

### Example 1

An InZn target was sputtered by argon for twenty-four hours in a continuous operation at a constant power mode at a pressure of about 7 mTorr to produce a TCO on a glass substrate. The resulting indium-zinc oxide (IZO) film had a thickness of from 243-244 nm, a sheet resistance of from 21.4-21.6 ohm/square and a light transmission rate of from 87%-88%. The process was conducted with the benefit of a closed-loop feedback control of the cathode voltage as described in connection with FIG. 4.

As a comparison, a conventional TCO film utilizing a metal target made of AZO (Al:ZnO) with similar electrical properties as the IZO film had a thickness of 500-550 nm thickness, a sheet resistance of 23-24 ohm/square and a light transmission rate of 84-85%. Therefore, to achieve similar sheet resistance, only about half of the required AZO film thickness is needed with IZO films prepared in accordance with the present invention with an absolute light transmission gain of 3-4%.

### Example 2

The deposition rate from an InZn target was computed based on typical production runs of solar panels. At a power level of 10 kW, films having a thickness of about 243 nm were produced at a line speed of 40 cm/min. The dynamic deposition rate (DDR) was calculated to be 960 nm.cm/min/kW. Converted to effective deposition rate in nm/min, the deposition rate in this example is 756 nm/min at 10 kW. This deposition rate can be increased relatively easily to over 1 μm/min provided a higher power is used during the sputtering process.

1. A method of forming an indium-containing transparent conductive oxide film comprising:
a) reactive sputtering a metal target comprising indium in an oxygen-containing atmosphere to form an indium-containing oxide
b) depositing the indium oxide on a substrate to form said transparent conductive oxide film.

2. The method of claim 1 wherein the metal target further comprises a metal selected from the group consisting of zinc, gallium and aluminum and combinations thereof.

3. The method of claim 1 wherein the step of reactive sputtering comprises contacting the metal target with an inert gas under conditions sufficient to sputter the metal from the target.

4. The method of claim 3 wherein the inert gas is argon.

5. The method of claim 1 further comprising controlling the quantity of oxygen in the oxygen-containing atmosphere.

6. The method of claim 5 wherein the step of controlling the quantity of oxygen comprises monitoring a variable selected from the group consisting of voltage, O₂ partial pressure and O₂ plasma emission and associating the variable with the flow of oxygen.

7. The method of claim 1 wherein the metallic target is in the form of a rotatable cylinder.

8. The method of claim 1 wherein the metallic target is planar.

9. The method of claim 1 wherein the metal target comprises indium and zinc.

10. The method of claim 9 wherein the step of the reactive sputtering frees indium and zinc from the target.

11. The method of claim 9 wherein the target comprises InₓZn₁₋ₓ wherein x is in the range of from about 0.01 to 0.95.

12. The method of claim 11 wherein x is in the range of from about 0.6 to 0.9.

13. A photovoltaic device comprising a substrate, a transparent conductive layer and an absorber layer between the substrate and the transparent conductive layer, said transparent conductive layer formed by the method of claim 1.

14. The photovoltaic device of claim 13 wherein the metal target further comprises a metal selected from the group consisting of zinc, gallium and aluminum and combinations thereof.

15. The photovoltaic device of claim 13 wherein the step of reactive sputtering comprises contacting the metal target with an inert gas under conditions sufficient to free the metal atoms from the target surface.

16. The photovoltaic device of claim 15 wherein the inert gas is argon.

17. The photovoltaic device of claim 13 further comprising controlling the quantity of oxygen in the oxygen containing atmosphere.

18. The photovoltaic device of claim 17 wherein the step of controlling the quantity of oxygen comprises monitoring a variable from the group consisting of voltage, O₂ partial pressure and O₂ plasma emission and associating the variable with the flow of oxygen.

19. The photovoltaic device of claim 13 wherein the metallic target is in the form of a rotatable cylinder.

20. The photovoltaic device of claim 13 wherein the metallic target is planar.

21. The photovoltaic device of claim 13 wherein the metal target comprises indium and zinc.

22. The photovoltaic device of claim 13 wherein the target comprises InₓZn₁₋ₓ and wherein x is in the range of from about 0.01 to 0.95.

23. The photovoltaic device of claim 22 wherein x is in the range of from about 0.6 to 0.9.

24. The photovoltaic device of claim 13 further comprising a transparent resistive layer between the transparent conductive layer and absorber layer.

25. The photovoltaic device of claim 24 wherein the transparent resistive layer comprises an oxide selected from IGZO and IAZO.

26. The photovoltaic device of claim 13 having a light transmission rate of at least 85%.
